(19) United States
(12) Patent Application Publication
(10) Pub. No.: US 2002/0157055 A1
(43) Pub. Date: Oct. 24, 2002

(54) Method and device for encoding information words, method and device for decoding information words, storage medium and signal

(75) Inventors: Willem Marie Julia Marcel Coene, Eindhoven (NL); Marten Erik Van Dijk, Eindhoven (NL); Constant Paul Marie Jozef Baggen, Eindhoven (NL)

Correspondence Address: Corporate Patent Counsel, U.S. Philips Corporation, 580 White Plains Road, Tarrytown, NY, 10591, US

(73) Assignee: Koninklijke Philips Electronics N.V.

(21) Appl. No.: 10/122,665

(22) Filed: Apr. 15, 2002

(30) Foreign Application Priority Data
Apr. 19, 2001 (EP) 01201416.3

(51) Int. Cl. H03M 13/00

(52) U.S. Cl. 714/758

(57) ABSTRACT

The invention relates to a method and device for encoding information words and a method and device for decoding as well as a storage medium for storing and a signal comprising such encoded information words. In order to improve the properties of a burst-indicator subcode it is proposed to encode the bits of a burst-indicator subcode byte into different channel words. Thus, these bits are spread over an entire frame of encoded data improving burst error detecting and correcting properties.

The invention relates to a method for encoding information words comprising the steps of encoding said information words into an error correction code comprising error correction code words, encoding said error correction code words into a modulation code comprising channel words, thereby using a burst-indicator subcode capable of indicating burst errors, said burst-indicator subcode comprising burst-indicator subcode bytes including a number of burst indicator subcode bits.

Furthermore, the invention relates to a method for decoding information words comprising the steps of decoding a modulation code comprising channel words in order to achieve error correction code words of an error correction code, decoding said error correction code words in order to achieve said information, thereby using a burst-indicator subcode for indicating burst errors, said burst indicator subcode comprising burst-indicator subcode bytes including a number of burst-indicator subcode bits.

Furthermore, the invention relates to a device for thus encoding information words according to the preamble of claim 15.

Furthermore, the invention relates to a device for thus decoding information words according to the preamble of claim 16.

Furthermore, the invention relates to a storage medium storing thus encoded information and a signal comprising a stream of channel words containing thus encoded information words.

In the field of optical recording an optical disc system comprises an error correction code (ECC) process and a modulation process to encode ECC code words.

For example, for the practical case of DVR the ECC process uses an error correction code of the format of a long-distance ECC code (LDC) in combination with a burst-indicator subcode (BIS). The LDC code consists of a [248, 216, 33] Reed-Solomon Code. The BIS code consists of a [62, 30, 33] Reed-Solomon Code. The BIS code carries address and control information and is very strongly protected, so that with extremely high probability the BIS code can be properly decoded, i.e., all of its errors can be corrected.

The reason for this kind of coding is that in the field of DVR the spot size of a laser spot on the entrance surface of a DVR disc is reduced from approximately 0.50 mm diameter for DVD discs to 0.14 mm diameter. This results in increased sensitivity to dust and scratches on the disc surface, which may cause burst errors, on top of the usual random errors during read out of the recording layer. The above-mentioned ECC code uses two correction mechanisms to handle these errors effectively, namely the LDC combined with the BIS.

A location of corrected bytes of the BIS code and a location of SYNC-patterns that are in error are used as so-called pickets indicating the position of likely long burst errors in the LDC data between these pickets. When subsequent pickets are erroneous, it is highly likely that all the data located physically in between these pickets was also detected erroneously. The LDC can use this information to perform erasure correction. Thereby, the BIS-bytes are encoded with a modulation code in the modulation process that is the same modulation code as for the LDC bytes.

Such an optical disc system is disclosed in the article “Optical Disc System for Digital Video Recording”, Proceedings ISOM/ODS, Hawai, 1999, SPIE Vol. 3864, pp. 50-52 T. Narahara, S. Kobayashi, M. Hattori, Y. Shimpuku, G. van den Enden, J. Kahlman, M. van Dijk, R. van Woudenberg.

Further BIS systems are disclosed in WO 00/07300 and WO 99/34271.

However, there are still burst errors that are not detected by this known system, since they are located between two pickets without effecting both adjacent pickets. Furthermore, the tails of long burst errors are also not detected by this prior art system.

It is therefore an object of the invention to improve burst error detection.

This object is achieved by providing a method for encoding information according to the above-mentioned type characterized by encoding the burst indicator subcode bits of each burst-indicator subcode byte into different channel words.

The object is further achieved by providing a method for decoding information according to the above-mentioned type being characterized by decoding the burst-indicator subcode bits from different channel words.

The object is further achieved by providing a device for encoding information according to claim 15.

The object is further achieved by providing a device for decoding information according to claim 16.

The object is further achieved by providing a storage medium storing encoded information being encoded according to claim 17.

Furthermore, the object is achieved by providing a signal comprising a stream of channel words containing encoded information words, in particular for use in internet applications, e.g. for applications transmitting information without the need of a storage medium.

The invention enables spreading the burst-indicator subcode bits over an entire frame of channel words. A frame is typically a group of channel words preceded by synchronization pattern. Whereas in known systems the BIS-bits are grouped into 3 bytes, according to the invention a fine rake—much more sensible to burst errors than a much coarser rake of a number of (3) BIS-bytes according to the prior art—of a large number of isolated BIS-bits for the detection of burst error events is provided.

Thus, the detection of burst errors is improved. As a result the error correction code properties can be improved as well.

Preferably, the BIS-bits are encoded into a particular characteristic property of different channel words, in particular in the parities of the channel words, in particular in the words that are encoded with a substitution code of the modulation code. Such combination of a main code and a substitution code is known as a combi code.

Preferably, the substitution code uses two possible channel words having opposite parity and a same next-state in an underlying finite-state machine. Thus, a DC-control of a signal containing the channel words can be established in a simple manner and particularly without adding a lot of redundancy, and thus keeping the code rate high.

Furthermore, it is preferred to encode the error correction code words in channel words by means of a main code of the modulation code, the substitution code, or the substitution code having a burst-indicator subcode bit encoded in the parities of the channel words. It should be noted that the information of the BIS bits can be encoded either in the parity of the channel words used for the substitution code or in the order in which the channel words of the substitution code appear in the code table of the substitution code. Thus, a high code rate can be obtained, thereby preserving high error correction properties and low or no DC-content in the channel signal.

Preferably, the BIS-bits are spread over an entire frame of channel words. Thus, burst error indication is enabled substantially over an entire frame and thus over an entire data block or data cluster. This spreading allows to detect even short burst errors and thus improves the error correction properties of the coding system.

Furthermore, it is preferred to assign erasures for the error correction code decoding based on detected erroneous BIS-bits. Thus, it is possible to eliminate burst errors with high reliability.

Furthermore, it is preferred to use a variable length code as the modulation code, such as a 17PP code which has a high coding efficiency.

These and other aspects of the invention will be apparent from and elucidated with reference to the embodiments described hereinafter with reference to the accompanying drawings, in which:

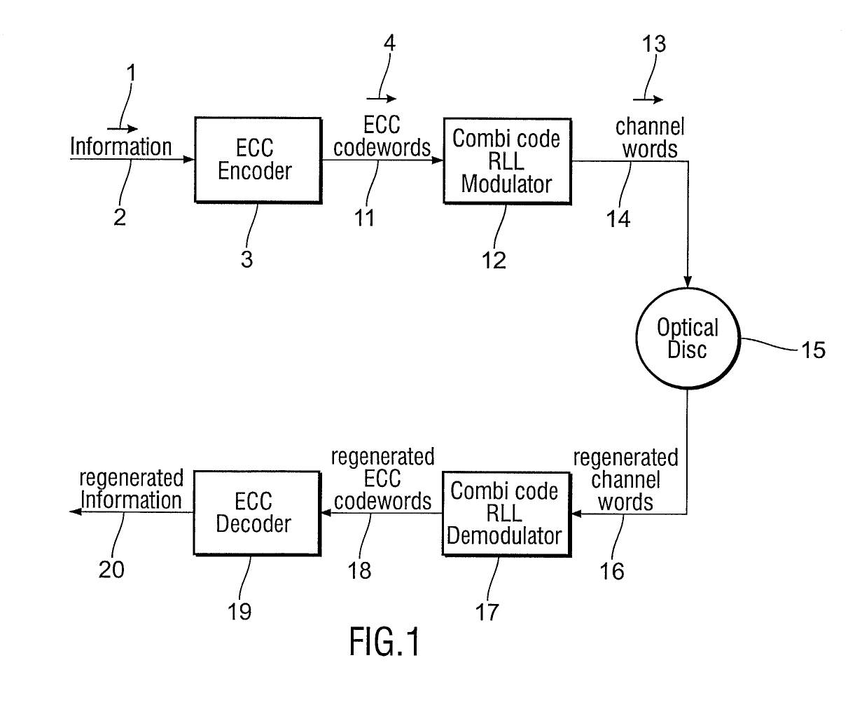

FIG. 1 shows a schematical diagram of a DVR system with ECC encoder, channel encoder, storage medium, channel decoder and ECC decoder;

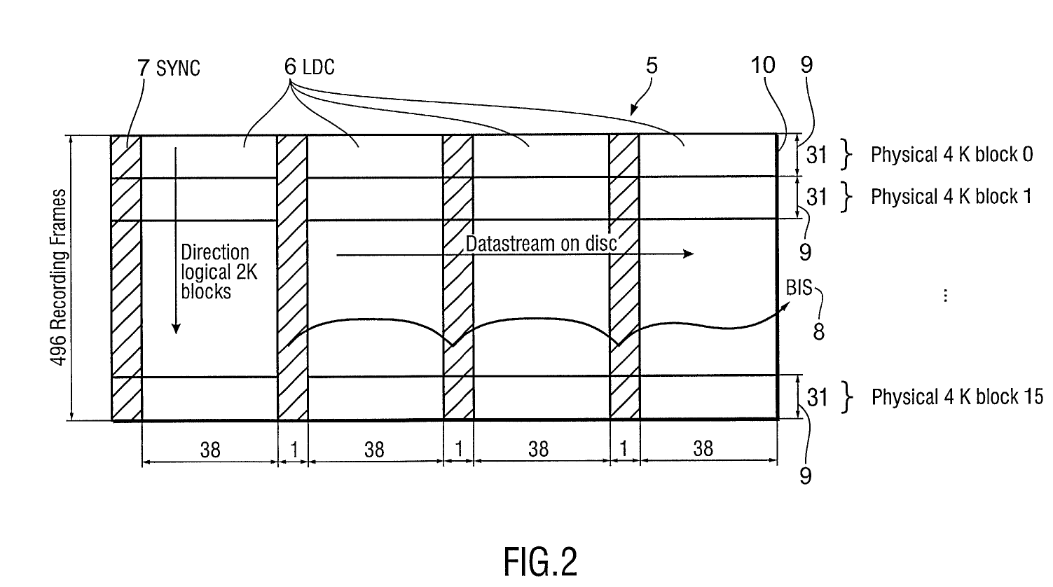

FIG. 2 shows a known ECC structure of a 64 Kbyte physical cluster with burst-indicator subcode columns;

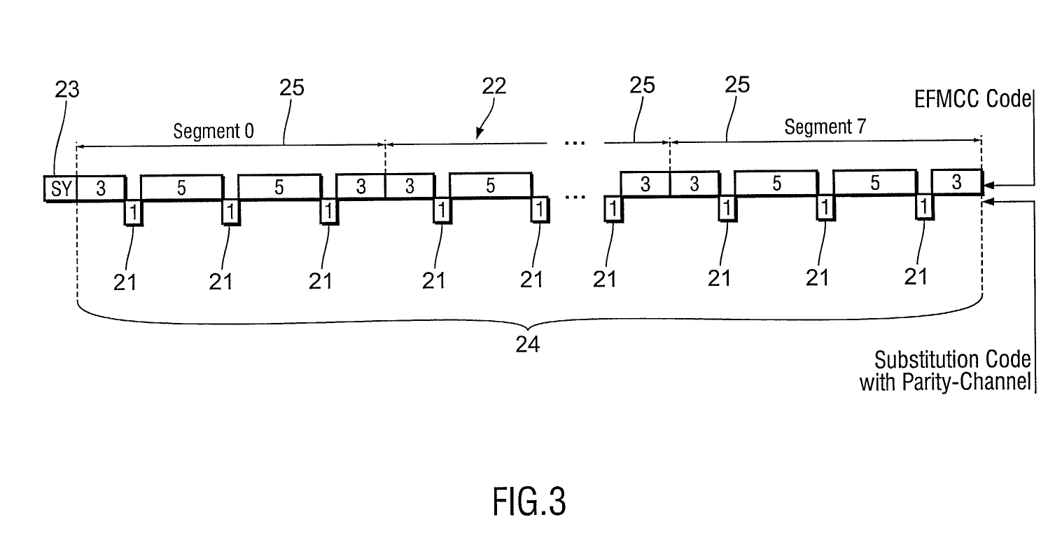

FIG. 3 shows a frame format for 152 bytes with inclusion of 24 burst-indicator subcode bits via the parity channel of a substitution code according to a preferred embodiment of the invention; and

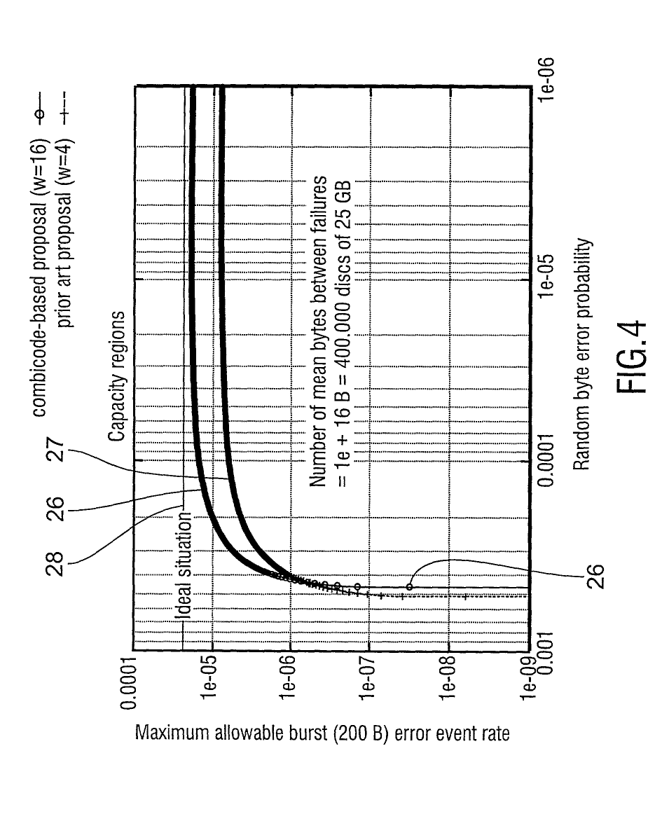

FIG. 4 shows a diagram illustrating the ECC performance of burst-indicator subcode-code for the prior art DVR proposal in comparison with a EFMCC proposal according to an embodiment of the invention.

FIG. 1 shows the principle structure of a DVR system. An information bit stream 1 is set via a signal line 2 to a ECC encoder 3. The ECC encoder 3 applies error-correction coding on the information bit stream 1 thereby generating ECC code words 4.

The ECC encoder 3 preferably uses a long-distance ECC code (LDC) such as a Reed-Solomon Code. The codes are designed such that most occurring combinations of random byte errors and burst errors can be corrected. Random byte errors are among others due to jitter causing a demodulator to output erroneous bytes. Bursts of errors are due to e.g. dust, finger prints, scratches, etc.

FIG. 2 shows a commonly used ECC structure for DVR. This code uses two correction mechanisms, namely a long-distance code (LDC) combined with a burst-indicator subcode(BIS).

The long-distance code consists of 304 [248, 216,33] Reed-Solomon code words per cluster 5. A logical 2 Kbyte information block is arranged in 9.5 Reed-Solomon code words in addition with four additional bytes used for extra error detection. The LDC is designed such that it has sufficient parity symbols and interleaving lengths for correcting random errors, multiple long bursts and short bursts of errors. The burst error correction capability can be enhanced by using erasure correction on symbols that are indicated as being erroneous by a BIS code.

Bytes 6 of LDC are multiplexed with synchronization patterns 7 and bytes 8 of the burst-indicator subcode.

The burst-indicator subcode has 24 [62, 30, 33] Reed-Solomon code words and carries address and control information. Due to the high distance of the [62, 30, 33] Reed-Solomon code which results in a low code rate, the code words of the burst-indicator subcode are strongly protected against errors. Therefore, the burst-indicator subcode can be properly decoded with a very high probability.

The location of its corrected bytes and erroneous synchronization patterns serve as “pickets” indicating the likely position of long burst errors in the LDC data between these pickets. It is assumed, that in case that subsequent pickets have been detected as erroneous, that all data located physically in between these pickets are also detected erroneously. In such a case the long-distance code can use this information to perform erasure correction.

Erasures are allocated to bytes that are most probable in error because they are part of an assumed burst of errors. The burst of errors is indicated by a certain strategy, based on BIS-bits (or BIS-bytes) that are in error. Therefore, a strong error correction code is applied on the information of the BIS-bytes, so that the BIS-bytes can be decoded free of any error.

A physical cluster 5 consists of 64 Kbyte user data organized in 16 physical 4 Kbytes blocks 9. Each block 9 is again subdivided into 31 recording frames 10. If it is desired to obtain the user data of one logical 2 Kbytes block it is only necessary to decode the burst-indicator subcode having all address information together with the corresponding 10 Reed-Solomon code words in the LDC 6. As it is not necessary to fully decode a 64 Kbyte LDC cluster 5 quick access to a logical 2 Kbyte block is enabled.

Referring back to FIG. 1 such ECC code words 4 are transmitted via a signal line 11 to a channel modulator/encoder 12.

In particular a channel code generated by the channel modulator 12 is designed based on the principles of combi codes. Furthermore, the channel code can be designed with EFM (Eight-To-Fourteen-Modulation)-like RLL (Run Lengths Limited) constraints (d=2, k=10). RLL sequences have a minimum run length of d+1 channel bits and a maximum run length of k+1 channel bits. These codes used for optical recording are DC-free, i.e. they have almost no content at low frequencies. The DC-free property is needed in order to separate the information signal from low-frequency disc noise, which is needed in order to control the slicer level, which is the basis for the timing recovery and in order to avoid interference of the information signal with servo systems. The DC-control of the RLL sequences is performed via control of a Running Digital Sum (RDS). The RDS is the integral of the bipolar channel bit stream up to a given bit position. Such a code is known as EFMCC. This code is a combination code, that is based on a combination of two channel codes C1 and C2, which both operate on a byte-by-byte basis. Both codes are constructed based on a FSM (Finite State Machine) consisting of a predetermined number, preferably of 6 states.

Further details of such codes are described in W. M. J. Coene, E. Chuang, “EFMCC: a new combi-code for high-density optical recording”, Proceedings of the SPIE, Optical Data Storage 2000 (Whistler, Canada), Volume 4090, pp. 275-282 and W. M. J. Coene, “Combi-Codes for DC-Free Runlength-Limited Coding”, IEEE Transactions on Consumer Electronics, Nov. 2000, Vol. 46, Nr. 4, pp. 1082-1087 which are hereby incorporated by reference.

Code C1 is called the main code, and maps a byte into a 15-bit channel word. Thereby a high coding rate is realized. Code C2 is called the substitution code, and maps a byte into one out of two possible 17-bit channel words. The goal of the code C2 is to achieve a guaranteed DC-control.

Both 17-bit channel words of the substitution code C2 satisfy the following two conditions for each of the coding states of the FSM. The first condition is that both channel words have opposite parity. The second condition is that both channel words have the same next-state in the FSM.

The EFMCC coding for a given format is based on an alternation scheme that defines the order in which the main code C1 and the substitution code C2 will be used for encoding of ECC code words 4.

The data encoded by the channel modulator 12 are output as channel words 13 via an electrical line 14 in order to be recorded on a storage medium 15, such as a DVR disc.

The code words 4 encoded with the substitution code C2 are the points in the channel bit stream 13 that allow for control of the DC-content. The parity selection at the substitution code C2 determines the polarity of the channel bit stream 13 for the subsequent code words all encoded with the main code C1, up to the next code word encoded with the substitution code C2.

The substitution code C2 of the EFMCC is in fact a parity-check code. Thus, the parity of the channel words can be controlled.

The channel words 13 stored on the storage medium 15 can be read by a reading device regenerating the channel words and passing them via a signal line 16 to a channel demodulator or channel decoder 17 being matched to the channel modulator or channel encoder 12.

The channel demodulator 17 regenerates the ECC code words and transmits the regenerated ECC code words via a signal line 18 to a ECC decoder 19 that regenerates the original information 1 and outputs this regenerated information to an output 20.

It is proposed to encode the bits of the BIS-bytes 8 (FIG. 2) into a separate channel on top of the RLL channel. This separate channel is the parity channel that can be associated with the encoding of LDC bytes 6 with the substitution code C2 of the EFMCC. The idea is to use the parity selection of the substitution code C2 to accommodate a BIS-bit for burst-indication. Preferably, three BIS-bytes, i.e. 24 BIS-bits are needed for a single frame in the DVR format.

As a result three classes of LDC bytes 6 are provided:

A first class of LDC bytes 6 encoded with the main code C1 of EFMCC is provided.

A second class of LDC bytes encoded with the substitution code C2 of EFMCC, in view of DC-control is provided.

A third class of LDC bytes encoded with the substitution code C2 of EFMCC is provided with the accommodation of a BIS-bit in the parity of the corresponding 17-bit channel word of the substitution code. Alternatively, the BIS-bit can be encoded in the use of either the first or the second channel word that are present as entries in the coding table of the substitution code C2.

In the third class, the 17-bit channel word represents 9 bits of information, i.e. 8 bits corresponding to the LDC byte and an additional bit, the parity bit of the channel word, corresponding to the BIS-bit.

Thus, it is possible to spread individual BIS-bits over an entire frame 10, whereas in the prior art proposal the BIS-bits are grouped into three bytes. Therefore, according to the invention a fine rake of 24 isolated BIS-bits for the detection of burst errors is provided. In contrast to this, the known coding scheme has a much coarser rake of 3 BIS-bytes, as shown in FIG. 2.

FIG. 3 shows a symmetrical dispersion of 24 BIS-bits 21 over a frame 22 comprising a sync-pattern 23 and 152 LDC bytes 24, according to a preferred embodiment of the invention.

Each frame 22 is divided into eight segments 25. Each segment 25 comprises 19 bytes having the following structure:

3B 1S 5B 1S 5B 1S 3B.

This structure is repeated eight times in a frame 22. The bytes denoted by B are encoded with EFMCC, namely either with the main code C1 or the substitution code C2. The bytes denoted by S are encoded with the substitution code C2 of EFMCC in order to accommodate the BIS-bits. Each segment 22 contains three BIS-bits, thus in total yielding 24 BIS-bits or 3 BIS-bytes for an entire frame 22.

This structure can be expressed in more general terms as:

number of bytes with the structure

x₁B 1S x₂B 1S x₃B 1S . . . xₙ₋₁B 1S xₙB 1S xₙ₊₁B

with the condition that x₁, x₂, x₃, . . . , xₙ₋₁, xₙ, xₙ₊₁ are integer values and 2ₓ₁, x₂, . . . , xₙ₋₁, xₙ, 2xₙ₊₁ are as close as possible to each other and wherein B denotes a byte encoded with said main code C1 or substitution code C2 without a burst-indicator subcode bit and S denotes a byte encoded with said substitution code 2C having a burst-indicator subcode bit.

As a result a fine rake of 24 pickets, namely the bytes B containing the 24 BIS-bits for indication of the location of burst errors is constituted. This location information can be used for the above-mentioned erasure strategy of the LDC code.

In each segment 25 the 3 BIS-bytes 21 are encoded with a rate R=½ because the channel words 13 of the substitution code C2 of EFMCC are two bits longer than the channel words of the main code C1 of EFMCC. According to the prior art they have been encoded via the main code C1 of EFMCC with a rate R=8/15. Thus, encoding of the 3 BIS-bytes 21 requires an extra overhead of 3 channel bits for one recording frame. However, as a frame length is about 2400 channel bits, this implies a relative overhead of only 1 promille.

The idea of encoding the bits of BIS-bytes into a separate channel on top of the RLL channel is in principle applicable to any code in which there is a possibility to perform a parity check on fixed locations in the channel bit stream over a fixed or known number of channel bits. According to the above described embodiment this is possible by the locations of the bytes intentionally encoded with the substitution code for the parity channel.

For rewritable discs a different format of channel modulation may be used, namely the so-called 17PP modulation code. The 17PP modulation code is a run length-limited (RLL) code based on (dk) sequences. The 17PP modulation code has run length constraints d=1, k=7. The DC-control is performed via the parity-preserving property of this code. This property implies that the parity of a code word and the parity of the corresponding channel word are equal. Further details of such code are described in U.S. Pat. No. 5,477,222 and WO 99/63671 which are hereby incorporated by reference.

The 17PP code is a variable-length synchronous code of rate R=⅔, in which a data word can have a length of 2, 4, 6 or 8 data bits and a corresponding channel word has a length of 3, 6, 9 or 12 channel bits.

The parity of parts of the (dk) channel bit stream can be controlled in a guaranteed way by multiplexing single DC-control bits in the data bit stream: changing a DC-bit from 0 to 1 changes the parity accordingly. Parity changes in the (dk) bit stream lead to polarity changes in the bipolar channel bit stream, and these are used to limit the value of the running digital sum RDS.

In the following it is explained how the above-mentioned approach of encoding the bits of the BIS-bytes into a separate channel on top of the RLL channel is adopted for the 17PP code for the rewritable format of DVR.

As the 17PP code is a variable length code based on 2, 4, 6 or 8 consecutive data bits and the parity-preserve property holds for the corresponding 3, 6, 9 or 12 channel bits the 17 PP code is parity-preserving in successive coding windows of variable size. This makes it impossible to derive the BIS-bits directly from the observation of the parity of a priori well defined parts of the channel bit stream. Therefore, it is proposed to perform detection of BIS-bits in the data bit stream, after a complete decoding of the channel bit stream. Thus, the idea of the invention is applicable to 17PP channel codes as well.

Two changes have to be performed compared to the prior art scheme using BIS bytes instead of BIS bits: A first change is the detection of the BIS-bits. When the combi code scheme is used, no RLL decoding is needed, only the detection of the parity of the channel words that accommodate the BIS-bits has to be carried out. A second change is that the erasure strategy of the ECC decoding has to be adapted.

FIG. 4 shows a diagram of the error correction code performance of the prior art BIS code in comparison with the combi code based proposal according to the invention. The horizontal axis indicates the random byte error probability before ECC decoding, whereas the vertical axis indicates the maximum allowable burst error event rate before ECC decoding.

Assumed that w is a parameter, called the window size, erasure strategies are considered in which all main bytes between two picket bytes/bits are erased if the two picket bytes/bits are close enough to one another, i.e. they are separated by at most w−2 picket bytes/bits, and if both are corrupted by errors that are detected during the BIS decoding.

Further, a fixed number of mean bytes between failures after ECC decoding and a fixed burst length of a burst error to be investigated is assumed. Then curve 26 indicates the curve of the combi code based proposal and curve 27 indicates the prior art proposal. The area below the curves 26, 27 indicates the capacity regions, that are defined as follows: any point below the curve leads to an acceptable number of mean bytes between failures after ECC decoding. The combi code based proposal approaches the ideal situation for small random byte error probabilities indicated by line 28 according to which the decoder is assumed to know the precise location of all bytes of a burst event. Compared to the prior art proposal according to curve 27 the combi code based proposal according to curve 26 is a factor of approximately 2.5 better for small random byte error probabilities.

In the prior art proposal a window size w=2 already achieves the depicted capacity region and in the combi code based proposal a window size w=8 already achieves the depicted capacity region. In general for all considered situations, w=2 suffices for the prior art proposal and w=8 suffices for the combi code based proposal according to the invention.

Summarized, the idea of encoding bits of a burst-indicator subcode into a separate channel on top of the RLL channel, in particular in the parity of channel words of the substitution code of combi code, thus enabling spreading the BIS-bits over an entire frame, provides a “fine-rake” burst-indicator subcode with improved error detecting and correcting properties.

1. A method for encoding information words (1) comprising the steps of
encoding said information words (1) into an error correction code comprising error correction code words (4),
encoding said error correction code words (4) into a modulation code comprising channel words (13),
thereby using a burst-indicator subcode (8, 21) capable of indicating burst errors, said burst-indicator subcode (8, 21) comprising burst-indicator subcode bytes including a number of burst indicator subcode bits
characterized by
encoding said burst-indicator subcode bits of each burst-indicator subcode byte into different channel words (13).

2. A method according to claim 1, characterized by encoding said burst-indicator subcode bits into a particular characteristic property of different channel words, in particular in the parities of said different channel words (13).

3. A method according to claim 1 or 2, characterized by encoding each of said burst-indicator subcode bits in the parities of said channel words (13) of a substitution code of said modulation code.

4. A method according to claim 3, characterized by said substitution code providing two possible channel words having opposite parity and a same next-state in a underlying finite-state machine.

5. A method according to claim 1, characterized by encoding said error correction code words (4) in channel words (13) with
a) a main code of said modulation code,
b) said substitution code of said modulation code, or
c) said substitution code of said modulation code having a burst-indicator subcode bit encoded in said parities of said channel words (13).

6. A method according to claim 1, characterized by spreading the burst-indicator subcode bits of a number of burst-indicator subcode bytes over an entire frame (22) of channel words (13).

7. A method according to claim 5 or 6, characterized in that said frame (22) comprises a number of segments (25), each segment (25) comprising a number of bytes with the structure
x₁B 1S x₂B 1S x₃B 1S . . . xₙ₋₁B 1S xₙB 1S xₙ₊₁B
with the condition that x₁, x₂, x₃, . . . , xₙ₋₁, xₙ, xₙ₊₁ are integer values and 2ₓ₁, x₂, . . . , xₙ₋₁, xₙ, 2xₙ₊₁ are as close as possible to each other and wherein B denotes a byte encoded with said main code or substitution code without a burst-indicator subcode bit and S denotes a byte encoded with said substitution code having a burst-indicator subcode bit.

8. A method according to claim 7, characterized in that x₁₊ᵢ is equal to 3, x₂₊ᵢ is equal to 5 and x₃₊ᵢ is equal to 5 and x₄₊ᵢ is equal to 3, with i being the index of the segments whereby i=0,1,2,3, . . . , 7, the number of bytes of each segment is 19, each segment containing 3 burst-indicator subcode bits and each frame containing 24 burst-indicator subcode bits or 3 burst-indicator subcode bytes.

9. A method according to claim 1, characterized in that said modulation code is a variable length code.

10. A method according to claim 9, characterized in that said variable length code is a (1, 7) run length limited parity-preserve code.

11. A method for decoding information words (1) comprising the steps of
decoding a modulation code comprising channel words (13) in order to achieve error correction code words (4) of an error correction code,
decoding said error correction code words (4) in order to achieve said information (1),
thereby using a burst-indicator subcode (8, 21) for indicating burst errors, said burst indicator subcode (8, 21) comprising burst-indicator subcode bytes including a number of burst-indicator subcode bits,
characterized by
decoding said burst-indicator subcode bits from different channel words (13).

12. A method according to claim 11, characterized by decoding said burst-indicator bits from the parities of said channel words (13).

13. A method according to claim 11 or 12, characterized by assigning erasures for the error correction code decoding based on detected erroneous burst-indicator subcode bits in order to correct burst errors.

14. A method according to claim 11, 12 or 13, characterized by decoding information being encoded according to any of claims 1 to 10.

15. A method according to claim 11, in which an erasure strategy is based on window size w of successive burst indicator subcode bits, allocating the erasure if or on condition that two successive erroneous burst indicator subcode bits are not more than w−2 locations away from each other.

16. A device for encoding information words (1) comprising
information encoding means (3) for encoding information words (1) into an error correction code comprising error correction code words (4),
code word encoding means (12) for encoding error correction code words (4) into a modulation code comprising channel words (13),
thereby using a burst-indicator subcode (8, 21) capable of indicating burst errors, said burst-indicator subcode comprising burst-indicator subcode bytes including a number of burst-indicator subcode bits,
characterized in that
said code word encoding means (12) encoding said burst-indicator subcode bits of each burst-indicator subcode byte into different channel words (13).

17. A device for decoding information words (1) comprising
code word decoding means (17) for decoding a modulation code comprising channel words (16) in order to achieve error correction code words (18) of an error correction code,
information decoding means (19) for decoding said error correction code words (18) in order to achieve said information (1),
thereby using a burst-indicator subcode (8, 21) for indicating burst errors, said burst-indicator subcode (8, 21) comprising burst-indicator subcodes bytes including a number of burst-indicator subcode bits,
characterized in that
said code word decoding means (17) decoding said burst-indicator subcode bits from different channel words (13).

18. A storage medium storing encoded information words (1) being encoded according to a method of any of claims 1 to 10.

19. A signal comprising a stream of channel words (13) containing encoded information words (1) being encoded according to a method of any of claims 1 to 10.
